(19) United States
(12) Patent Application Publication
(10) Pub. No.: US 2026/0129924 A1
(43) Pub. Date: May 7, 2026

(54) SEMICONDUCTOR DEVICE WITH ISOLATION STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: YU-WEI TSAO, TAIPEI CITY (TW); KUAN-JU CHEN, HSINCHU COUNTY (TW); KUAN-YU CHEN, TAOYUAN CITY (TW); CHING-HSIANG HSIEH, TAOYUAN CITY (TW); CHUNG-CHUAN TSENG, HSINCHU CITY (TW)

(21) Appl. No.: 18/939,578

(22) Filed: Nov. 7, 2024

(51) Int. Cl. H01L 29/06; H01L 21/306; H01L 21/3065; H01L 21/762

(52) U.S. Cl. CPC H10D 62/115; H10D 62/126; H10P 50/242; H10P 50/642; H10W 10/014; H10W 10/17

(57) ABSTRACT

A semiconductor device is provided. The semiconductor device includes a first semiconductive region, a second semiconductive region formed in the first semiconductive region and an isolation structure. The isolation structure includes an insulating bottom and a plurality of insulating pillars. The insulating bottom is formed between the first semiconductive region and the second semiconductive region. The plurality of insulating pillars are formed along a peripheral region of the insulating bottom at intervals and extend from the peripheral region of the insulating bottom toward a top of the first semiconductive region, so that the plurality of insulating pillars surround the second semiconductive region formed on the insulating bottom. The first semiconductive region and the second semiconductive region connect with each other through the intervals.

### BACKGROUND

Semiconductor devices are used in a large number of electronic devices, such as computers, cell phones, and others. Semiconductor devices comprise integrated circuits that are formed on semiconductor wafers by depositing many types of thin films of material over the semiconductor wafers, and patterning the thin films of material to form the integrated circuits. Integrated circuits include field-effect transistors (FETs) such as metal oxide semiconductor (MOS) transistors.

One of the goals of the semiconductor industry is to continue shrinking the size and increasing the speed of individual FETs. Silicon on insulator (SOI) devices have been recognized as one of the possible solutions to enable continued scaling. SOI devices offer a number of advantages over bulk devices. For example, SOI devices exhibit very low junction capacitance compared to bulk devices. The source and drain junction capacitances are almost entirely eliminated.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a perspective view of a semiconductor device, in accordance with some embodiments of the present disclosure.

FIG. 2 illustrates a top view of the semiconductor device shown in FIG. 1, in accordance with some embodiments of the present disclosure.

FIG. 3A illustrates a cross-sectional side view, which is along line A-A of the semiconductor device shown in FIGS. 1 and 2, in accordance with some embodiments of the present disclosure.

FIG. 3B illustrates a cross-sectional side view in accordance with some another embodiments of the present disclosure.

FIG. 4 illustrates a perspective view of a semiconductor device, in accordance with some another embodiments of the present disclosure.

FIG. 5 illustrates a top view of the semiconductor device shown in FIG. 4, in accordance with some another embodiments of the present disclosure.

FIG. 6A to 6F illustrate top views of the semiconductor device in accordance with various embodiments of the present disclosure.

FIG. 7A illustrates a top view of the semiconductor device in accordance with some another embodiments of the present disclosure.

FIG. 7B a cross-sectional side view along line B-B of the semiconductor device shown in FIG. 7A, in accordance with some embodiments of the present disclosure.

FIG. 8 illustrates a top view of the semiconductor device in accordance with some alternative embodiments of the present disclosure.

FIG. 9 is a flowchart of a method for forming the semiconductor device in accordance with some embodiments.

FIGS. 10A to 10D illustrate various perspective views of forming the semiconductor device in accordance with some embodiments as described in FIG. 9.

FIGS. 11A to 11D illustrate various cross-sectional side views along line C-C of the semiconductor device shown in FIGS. 10A to 10D, respectively, in accordance with some embodiments of the present disclosure.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

A comparative semiconductor-on-insulator (SOI) structure comprises a substrate, an insulator formed on the substrate and a layer of semiconductive material formed on the insulator, so that the insulator isolates the layer of semiconductive material from the substrate. However, such insulator can only provide a single-direction isolation and require high costs. Alternatively, anti-doped implantation may be conducted to provide a full direction junction isolation. However, such junction isolation may bring parasitic capacitance and would reduce device performance. Furthermore, such junction isolation introduces extra parasitic capacitance, which would reduce device performance. There is a need to provide a cost effective isolation structure with nearly full direction isolation using a simplified process.

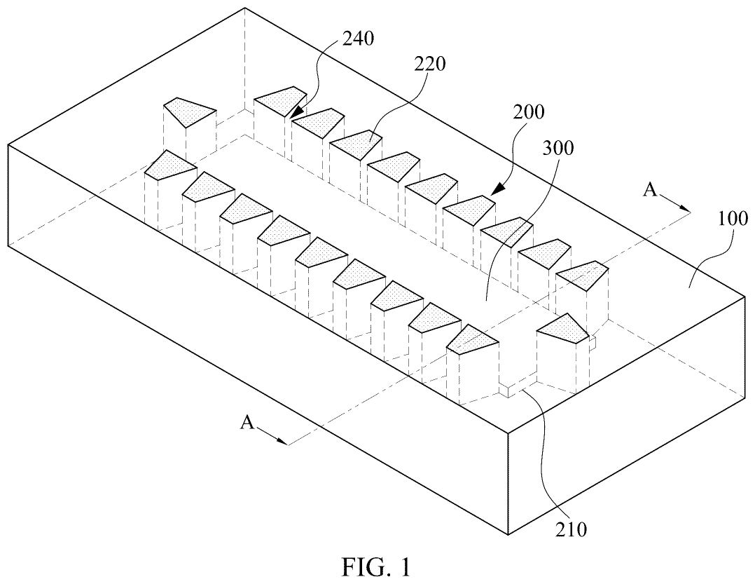

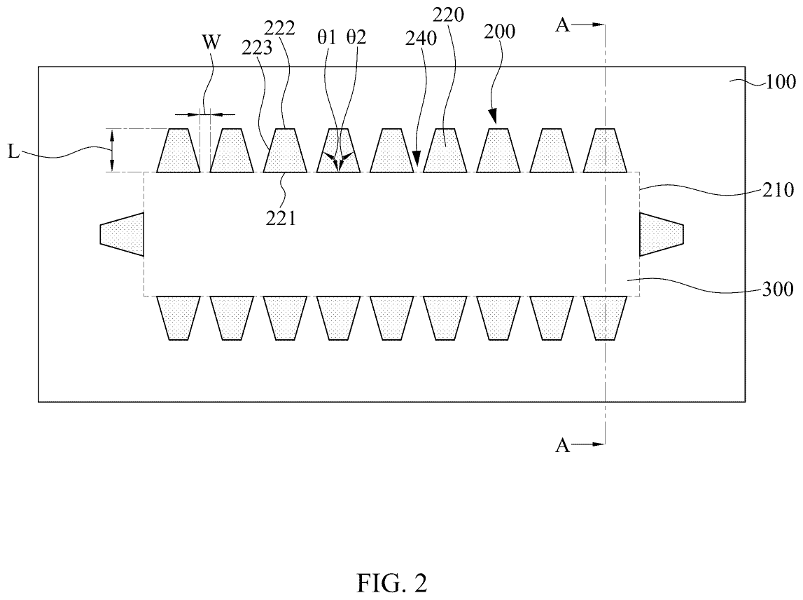

Referring to FIGS. 1 and 2, the semiconductor device includes a first semiconductive region 100, an isolation structure 20 and a second semiconductive region 300.

The first semiconductive region 100 may be formed in the semiconductor device using metal-organic chemical vapor deposition (MOCVD), molecular beam epitaxy (MBE), liquid phase epitaxy (LPE), vapor phase epitaxy (VPE), selective epitaxial growth (SEG), the like, or a combination thereof. In some embodiments, the first semiconductive region 100 comprises SiGe, Ge, GeSn, SiGeSn, or a III-V material. In embodiments wherein the first semiconductive region 100 comprises a III-V material, the first semiconductive region 100 may comprise InAs, AlAs, GaAs, InP, GaN, InGaAs, InAlAs, GaSb, AlSb, AlP, or GaP, as examples. The first semiconductive region 100 may comprise a thickness of about 3 nm to about 30 nm, or about 10 nm to about 20 nm, for example. The first semiconductive region 100 may also comprise other materials and dimensions, and may be formed using other methods.

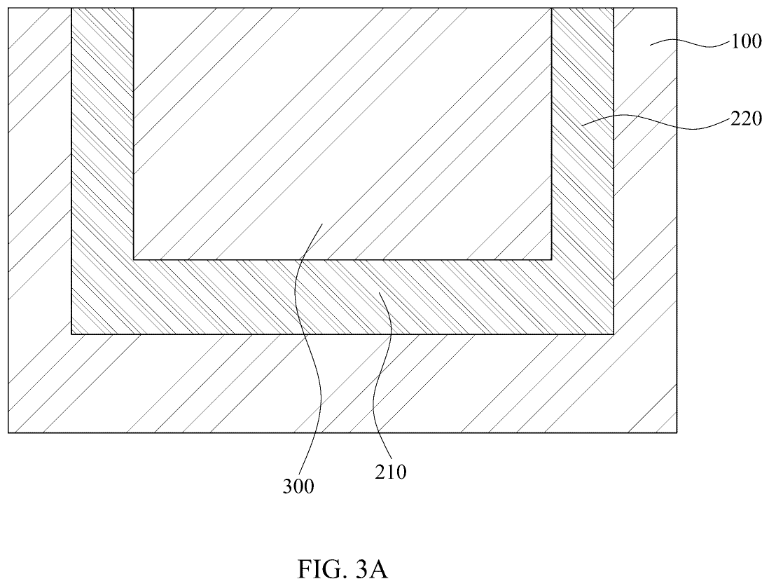

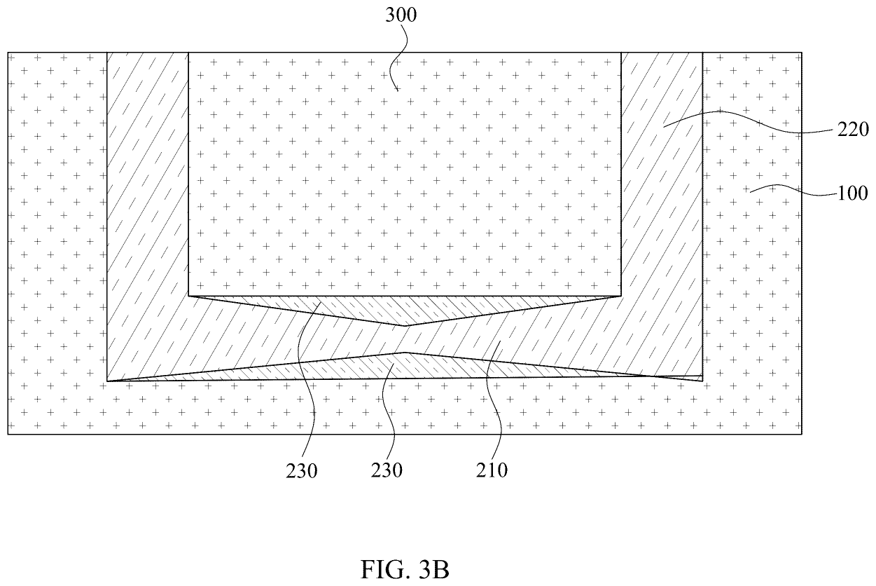

In some embodiments with reference to FIG. 3A, the isolation structure 200 is formed in the first semiconductive region 100 and has an insulating bottom 210 and a plurality of insulating pillars 220. A top of the isolation structure 200 may be coplanar with an upper surface of the first semiconductive region 100. The insulating bottom 210 is formed in the first semiconductive region 100 and may comprise oxide (such as SiO, doped SiO and so on), nitride (such as SiN), carbide (such as SiC), low k materials or a combination thereof. For example, the insulating bottom 210 may comprise silicon oxide, doped silicon oxide, silicon carbide, silicon nitride and so on. These are, of course, merely examples and are not intended to be limiting. The insulating bottom 210 has an upper surface, which may be parallel to the upper surface of the first semiconductive region 100 and may be apart from the upper surface of the first semiconductive region 100 with a predetermined distance.

In some another embodiments with reference to FIG. 3B, a thickness of the insulating bottom 210 may be gradually decreased from a peripheral edge of the insulating bottom 210 to a central portion of the insulating bottom 210. Therefore, the isolation structure 200 may further comprise at least one embedded doped region 230, which can be formed on the upper surface of the insulating bottom 210, or formed beneath the lower surface of the insulating bottom 210, or formed on the upper surface of the insulating bottom 210 and also beneath the lower surface of the insulating bottom 210. In some embodiments, the lower surface of the insulating bottom 210 may be an irregular surface and the upper surface of the insulating bottom 210 may also be an irregular surface, so that the thickness of the insulating bottom 210 is not uniform.

The embedded doped region 230 comprises materials with a high etching selectivity in respect to the first semiconductive region 100 and a second semiconductive region 300. For example, when the first semiconductive region 100 and the second semiconductive region 300 comprise P-type materials, the embedded doped region 230 may comprise highly doped p-type dopants (e.g., P+ dopants) or even heavily doped p-type dopants (e.g., P++ dopants). The p-type dopants may comprise B, Ga, or In implanted to a concentration equal to or greater than about 10¹⁵ atoms/cm⁻³. In some embodiments, the concentration may range from about 10¹⁵ atoms/cm⁻³ to 10²⁰ atoms/cm⁻³. When the first semiconductive region 100 and a second semiconductive region 300 comprise n-type materials, the embedded doped region 230 may comprise highly doped n-type dopants (e.g., N+ dopants) or even heavily doped n-type dopants (e.g., N++ dopants). The n-type dopants may be phosphorus, arsenic, other n-type dopant, or combinations thereof. The volume of the embedded doped region 230 may be varied depending on the dimension of the second semiconductive region 300.

The plurality of insulating pillars 220 are formed along a peripheral region of the insulating bottom 210 and extend from the peripheral region of the insulating bottom 210 toward the top of the first semiconductive region 100 as shown in FIGS. 3A and 3B so as to expose upper surfaces of the plurality of insulating pillars 220. In some embodiments, the plurality of insulating pillars 220 are formed at intervals 240, so that the first semiconductive region 100 and the second semiconductive region 300 connect with each other through the intervals 240. The insulating pillars 220 provide nearly-full insulator isolation on full direction. Each of the plurality of insulating pillars 220 has a lower portion connecting the insulating bottom 210. For example, the plurality of insulating pillars 220 may extend from a top of the peripheral region of the insulating bottom 210, or extend from a side of the peripheral region of the insulating bottom 210, or partially extend from the top of the peripheral region of the insulating bottom 210 or extend from the side of the peripheral region of the insulating bottom 210, so that the plurality of insulating pillars 220 partially surround the second semiconductive region 300 formed on the insulating bottom 210.

The second semiconductive region 300 is located on the insulating bottom 210 of the isolation structure 200 and is partially surrounded by the plurality of insulating pillars 220. The number of the insulating pillars 220 would vary depending on the isolation demand and the voltage applied to the semiconductor device, which provides design flexibility. In some embodiments, about 50% to 100% of side surface of the second semiconductive region 300 are surrounded by the plurality of insulating pillars 220. In some embodiments, about 50% to less than 100% of side surface of the second semiconductive region 300 are surrounded by the plurality of insulating pillars 220. In some embodiments, about 60% to about 95% of side surface of the second semiconductive region 300 are surrounded by the plurality of insulating pillars 220. In some embodiments, about 70% to about 90% of side surface of the second semiconductive region 300 are surrounded by the plurality of insulating pillars 220. The second semiconductive region 300 may have a material identical to the material of the first semiconductive region 100. A top of the second semiconductive region 300 is coplanar with the top of the first semiconductive region 100 and the top of the isolation structure 200. An area of the top of the second semiconductive region 300 may range from about 0.1 nm² to 107 mm². In some embodiments, the second semiconductive region 300 may connect the first semiconductive region 100 through the intervals 240 between the pluralities of insulating pillars 220.

In some embodiments, the insulating bottom 210 may be in any shape from a top view, including but not limited to a rectangular shape, a triangular shape, a circular shape, or other regular or irregular shapes. As shown in FIG. 2, the insulating bottom 210 may be a rectangular cuboid and thus is rectangular from the top view, so the insulating bottom 210 has a peripheral region including two long sides and two short sides. The plurality of insulating pillars 220 are formed along the long sides and short sides of the peripheral region of the insulating bottom 210. In some embodiments, the insulating pillars 220 may be symmetrically or asymmetrically formed along both long sides of the peripheral region of the insulating bottom 210 and the insulating pillars 220 may be also symmetrically or asymmetrically formed along both short sides of the peripheral region of the insulating bottom 210. As shown in FIGS. 1 to 3, the insulating pillars 220 are symmetrically formed along both of the long sides of the peripheral region of the insulating bottom 210 and the insulating pillars 220 are also symmetrically formed along both if the short sides of the peripheral region of the insulating bottom 210.

In some embodiments, all of the insulating pillars 220 may have an identical shape, in which a top cross section of each insulating pillar 220 may be a triangular top cross section, a rectangular top cross section (such as a trapezoid top cross section, a rhombus top cross section, a square top cross section and so on), a circular top cross section, a polygonal top cross section (such as pentagonal top cross section, hexagonal top cross section and so on). As shown in FIG. 2, each of the insulating pillar 220 has a trapezoid top cross section including a baseline 221, a topline 222 shorter than the baseline 221 in width and two sides 223. The baseline 221 and the topline 222 are parallel. In some embodiments, a length L between the baseline 221 and the topline 222 may range from about 0.1 μm to about 5 μm. In some embodiments, the length L between the baseline 221 and the topline 222 may range from about 0.5 μm to about 4 μm. In some embodiments, the length L between the baseline 221 and the topline 222 may range from about 0.8 μm to about 3 μm. In some embodiments, the length L between the baseline 221 and the topline 222 may range from about 1 μm to about 2 μm. The length between the baseline 221 and the topline 222 may vary depending on the isolation effect to be achieved.

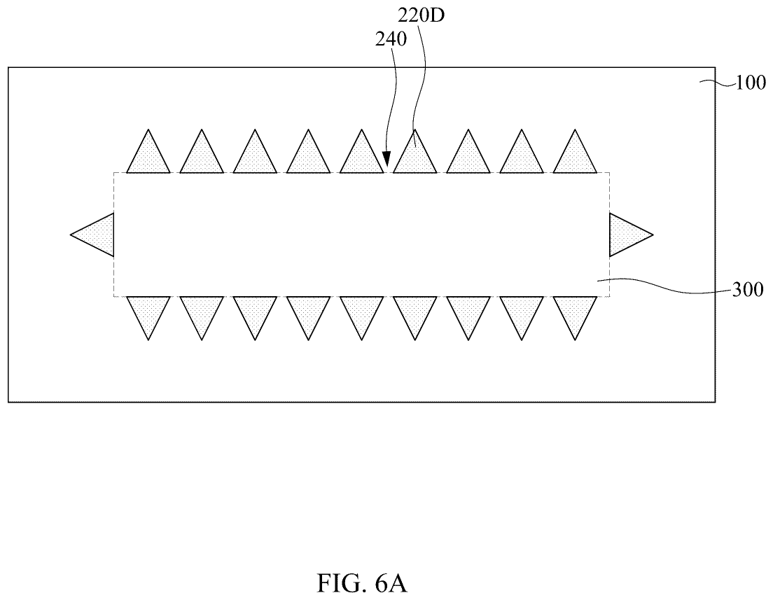

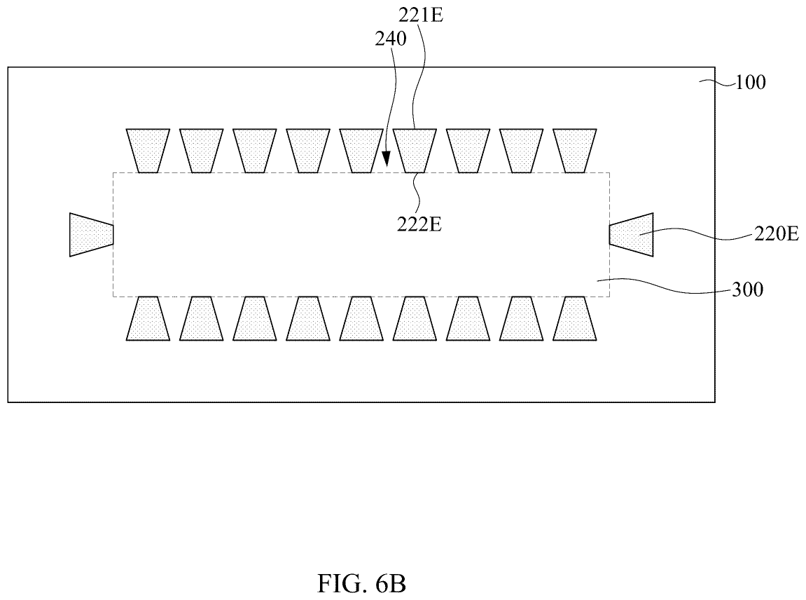

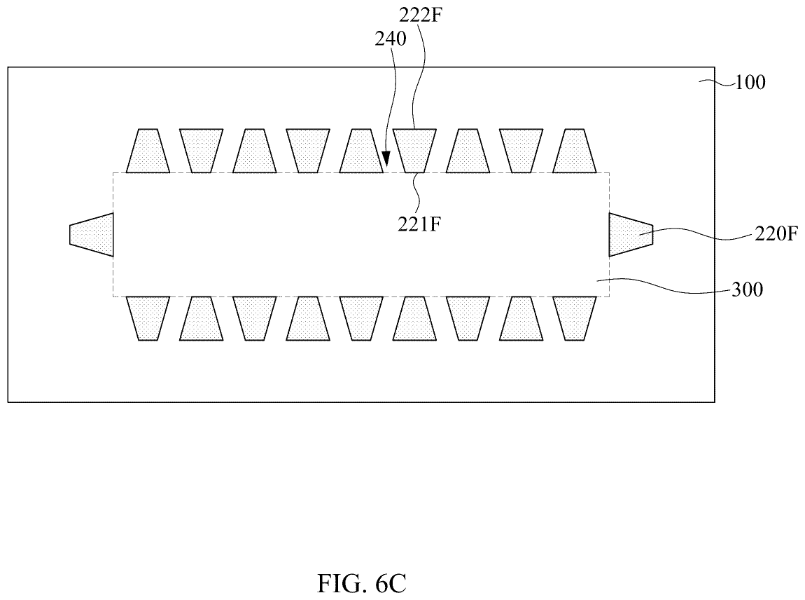

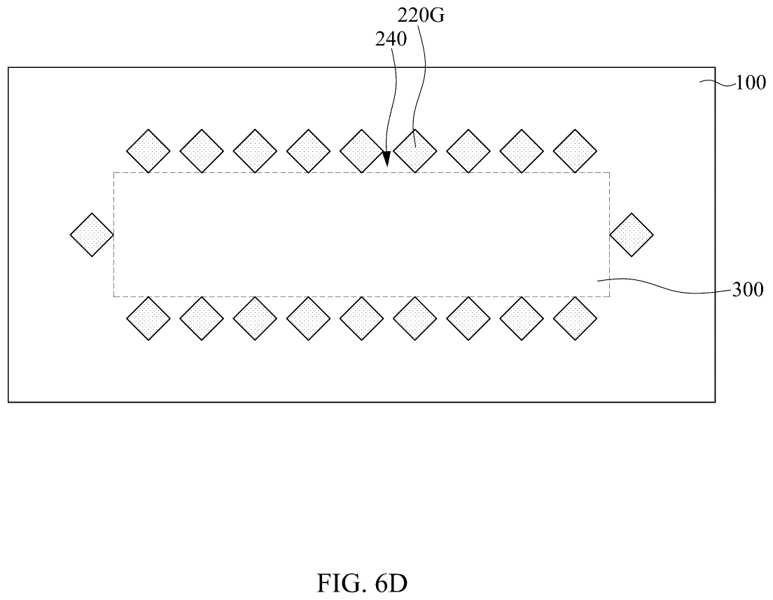

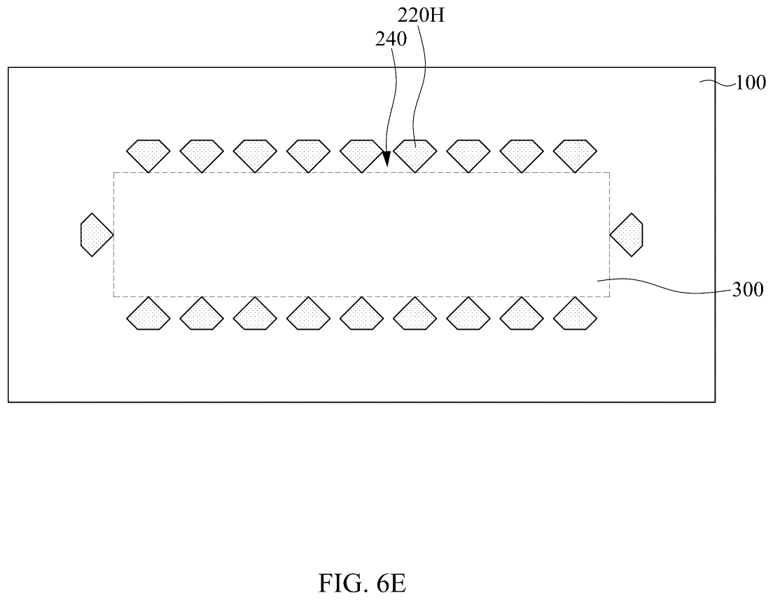

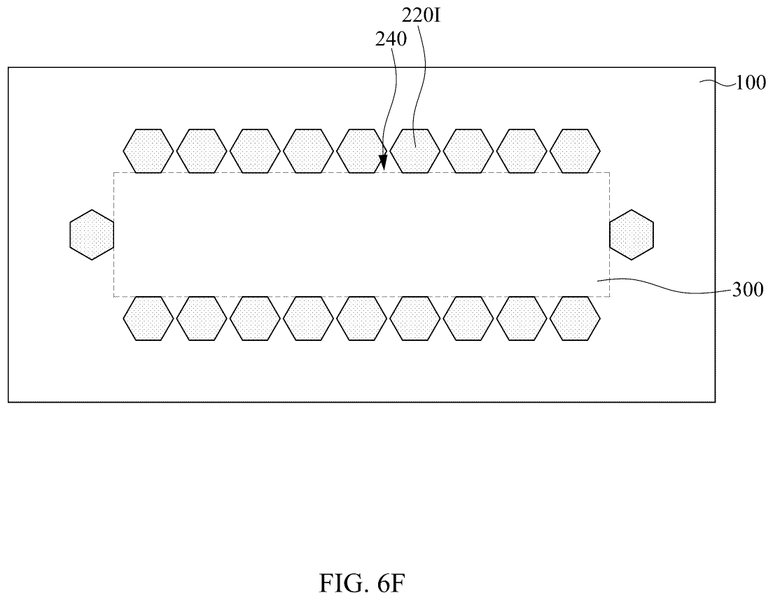

An angle θ1 between the baseline 221 and one side 223 may be identical to or different from an angle θ2 between the baseline 221 and the other side 223. As shown in FIG. 2, the angle θ1 is identical to angle the angle θ2. In some embodiments, the angle θ1 may range from about 15° C. to about 165° C. In some another embodiments, the angle θ1 may range from about 30° C. to about 150° C. In some alternative embodiments, the angle θ1 may range from about 45° C. to about 135° C. In some embodiments, the angle θ2 may range from about 15° C. to about 165° C. In some another embodiments, the angle θ2 may range from about 30° C. to about 150° C. In some alternative embodiments, the angle θ2 may range from about 45° C. to about 135° C. Therefore, in some embodiments, the baseline 221 may be longer than the topline 222. Further, in some embodiments, depending on the changes of the angle θ1 and the angle θ2, the shape of the insulating pillar 220 may be trapezoid or triangle from a top view. As shown in FIG. 2, the baseline 221 abuts the second semiconductive region 300 and the topline 222 is in the first semiconductive region 100. In some alternative embodiments, the baseline 221 may be shorter than the topline 222. As shown in FIG. 6A, the topline 222 abuts the second semiconductive region 300 and the baseline 221 is in the first semiconductive region 100. Each of the intervals 240 is formed between one side 223 of one trapezoid insulating pillar 220 and one side 223 of an adjacent trapezoid insulating pillar 220.

Each interval 240 is formed between two insulating pillars 220. The interval 240 between two insulating pillars 220 may have inconsistent width depending on the shapes of the insulating pillars 220. For example, as shown in FIGS. 1 and 2, since the baseline 221 of the trapezoid insulating pillar 220 is longer than the topline 222 of the trapezoid insulating pillar 220, the width of the interval 240 between the baseline 221 of the trapezoid insulating pillar 220 is less than that of the interval 240 between the topline 222 of the trapezoid insulating pillar 220. A narrowest width W of the interval 240 is greater than 0 μm. In some embodiments, the narrowest width W of the interval 240 between two insulating pillars 220 may range from about 0.1 μm to about 3 μm. In some embodiments, the narrowest width W of the interval 240 between two insulating pillars 220 may range from about 0.2 μm to about 2 μm. In some embodiments, the narrowest width W of the interval 240 between two insulating pillars 220 may range from about 0.5 μm to about 1.5 μm. In some embodiments, the narrowest width W of the interval 240 between two insulating pillars 220 may range from about 0.8 μm to about 1.2 μm.

In some embodiments, from a top view as shown in FIG. 2, a ratio of the narrowest widths of all of the intervals 240 to a perimeter of the second semiconductive region 300 may range from about 5% to about 40%. In some embodiments, the ratio of the narrowest widths of all of the intervals 240 to a perimeter of the second semiconductive region 300 may range from about 10% to about 35%. In some embodiments, the ratio of the narrowest widths of all of the intervals 240 to a perimeter of the second semiconductive region 300 may range from about 9% to about 33%. In some embodiments, the ratio of the narrowest widths of all of the intervals 240 to a perimeter of the second semiconductive region 300 may range from about 15% to about 30%.

In some embodiments, a ratio of the narrowest widths of all of the intervals 240 to total widths of the baseline 221 of all of the plurality of insulating pillars 220 may range from about 10% to about 50%. In some embodiments, the ratio of the total width of the intervals 240 to the total width of the baseline 221 of the plurality of insulating pillars 220 may range from about 15% to about 45%. In some embodiments, the ratio of the total width of the intervals 240 to the total width of the baseline 221 of the plurality of insulating pillars 220 may range from about 20% to about 40%. In some embodiments, the ratio of the total width of the intervals 240 to the total width of the baseline 221 of the plurality of insulating pillars 220 may be about 12%, about 16%, about 18%, about 21%, about 27%, about 29%, about 32%, about 34%, about 38%, about 43%, about 47%, about 49% or the like.

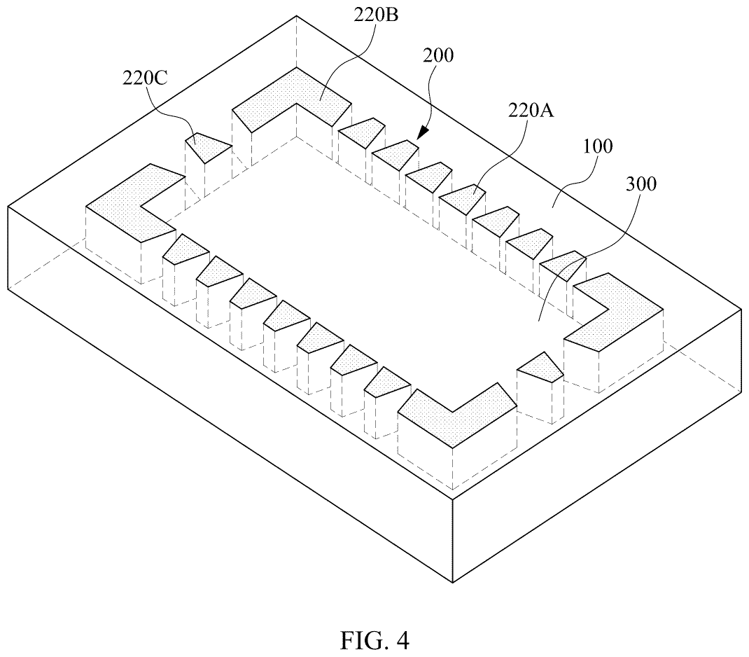

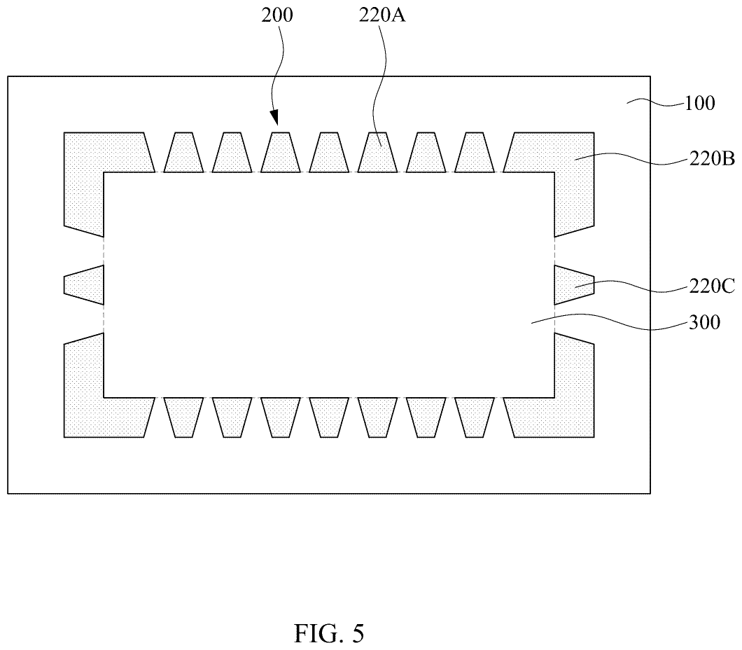

The plurality of insulating pillars 220 may be different in shape. For example, as shown in FIGS. 4 and 5, when the second semiconductive region 300 can be a tetrahedron, there are four L-shape insulating pillars 220B formed at four corners of the second semiconductive region 300 and several trapezoid insulating pillars 220A and 220C formed along four sides of the second semiconductive region 300 to surround the second semiconductive region 300.

In some alternative embodiments, each insulating pillar 220D may have a triangular top cross section, in which one of three side surfaces of the insulating pillar 220D abuts the second semiconductive region 300; and the insulating pillars 220D are arranged at intervals 240 as shown in FIG. 6A. In some alternative embodiments, each insulating pillar 220E may have a trapezoid top cross section, in which the topline 222E of each insulating pillar 220E abuts the second semiconductive region 300 while the baseline 221E of each insulating pillar 220E is in the first semiconductive region 100 as shown in FIG. 6B. In some alternative embodiments as shown in FIG. 6C, each insulating pillar 220F may have a trapezoid top cross section, in which the baseline 221F of one insulating pillar 220F abuts the second semiconductive region 300 while the topline 222F of an adjacent insulating pillar 220F abuts the second semiconductive region 300. One side 223 of one trapezoid insulating pillar 220 may be parallel with an adjacent side 223 of an adjacent trapezoid insulating pillar 220, so an interval 240 is formed between two trapezoid insulating pillar 220.

In some alternative embodiments, each insulating pillar 220G may have a rhombus top cross section and the insulating pillars 220G along long sides of the second semiconductive region 300 are formed at intervals 240 as shown in FIG. 6D. In some alternative embodiments, each insulating pillar 220H may have a pentagonal top cross section and the insulating pillars 220H along long sides of the second semiconductive region 300 are formed at intervals 240 as shown in FIG. 6E. In some alternative embodiments, each insulating pillar 220I may have a hexagonal top cross section and the insulating pillars 220I along long sides of the second semiconductive region 300 are formed at intervals 240 as shown in FIG. 6E.

In some embodiments, the insulating pillars 220 may all have the same insulating material, which may be identical to or different from the insulating bottom 210. The insulating pillars 220 may comprise oxide (such as SiO, doped SiO and so on), nitride (such as SiN), carbide (such as SiC), low k materials or a combination thereof. For example, the insulating pillars 220 may comprise silicon oxide, doped silicon oxide, silicon carbide, silicon nitride and so on. These are, of course, merely examples and are not intended to be limiting.

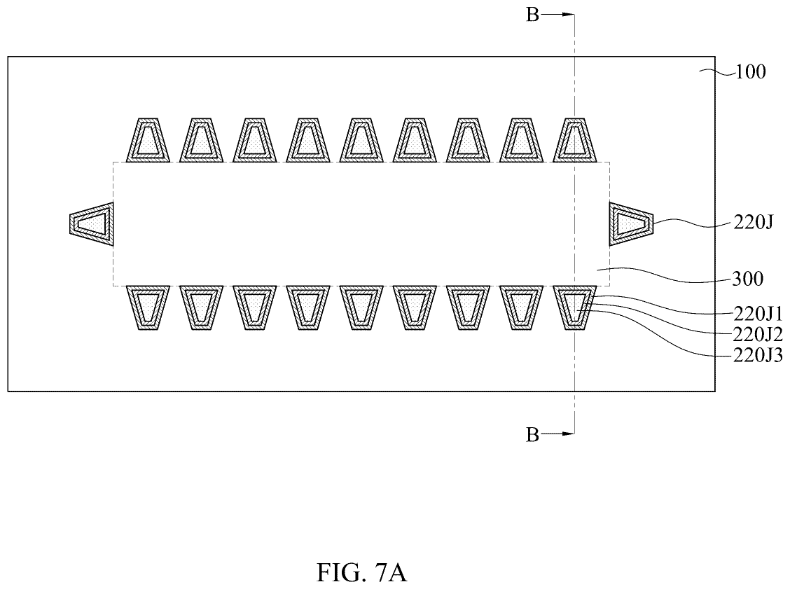

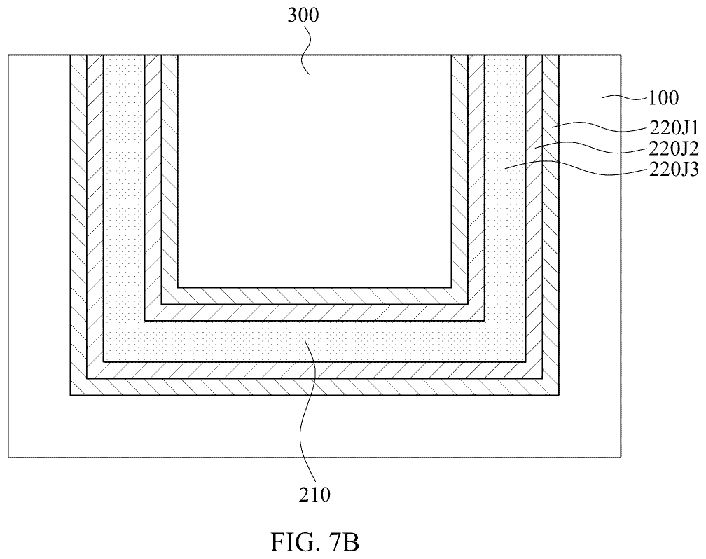

In some embodiments, each insulating pillar 220 may comprise two or more layers with different materials. As shown in FIGS. 7A and 7B, each insulating pillar 220J includes three layers including an outer layer 220J-1 partially connecting the first semiconductive region 100 and partially connecting the second semiconductive region 300, an intermediate layer 220J-2 surrounded by the outer layer 220J-1, and an inner layer 220J-3 surrounded by the intermediate layer 220J-2. For example, the outer layer 220J-1 includes oxides, the intermediate layer 220J-2 includes nitride, and the inner layer 220J-3 includes carbide. Furthermore, the insulating bottom 210 may also comprise two or more layers with different materials. As shown in FIGS. 7A and 7B, each insulating bottom 210 comprises several layers corresponding to the outer layer 220J-1, the intermediate layer 220J-2 and the outer layer 220J-1 of the insulating pillar 220.

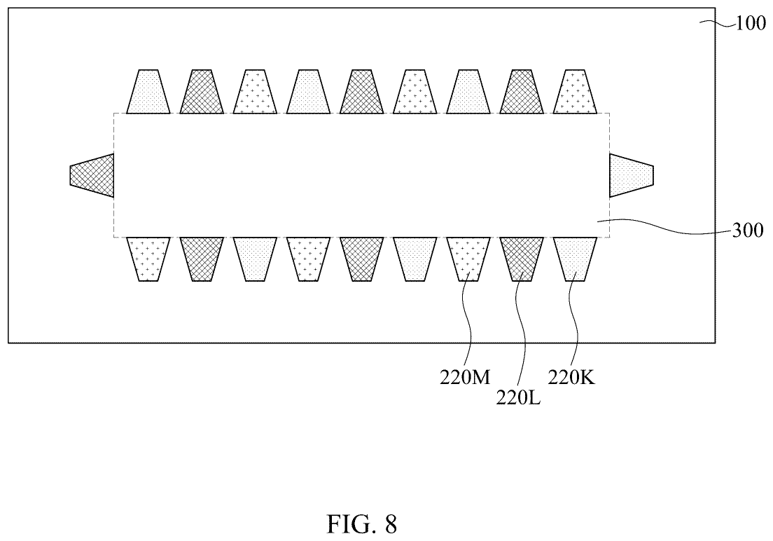

In some alternative embodiments, the plurality of the insulating pillar 220 may comprise different materials while each insulating pillar 220 comprise the same material. As shown in FIG. 8, a plurality of first insulating pillars 220K, a plurality of second insulating pillars 220L and a plurality of third insulating pillars 220M are formed alternately. For example, the first insulating pillars 220K comprise oxide; the second insulating pillars 220L comprise nitride; and the third insulating pillars 220M comprise carbide. These are, of course, merely examples and are not intended to be limiting.

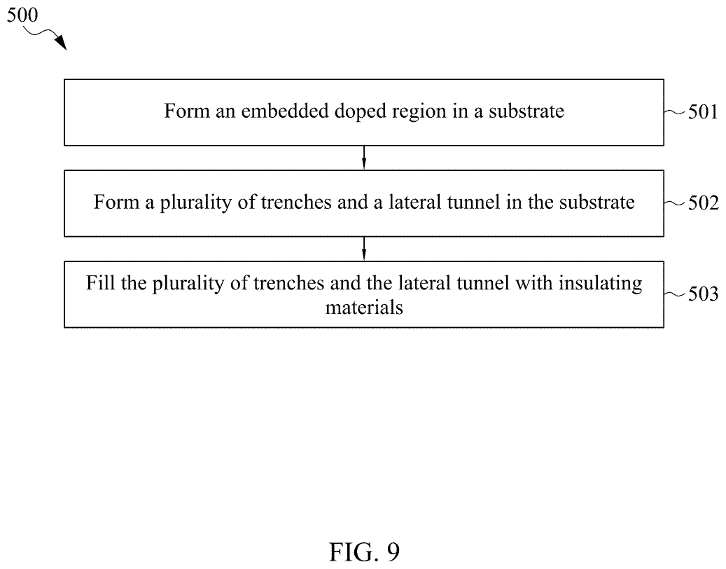

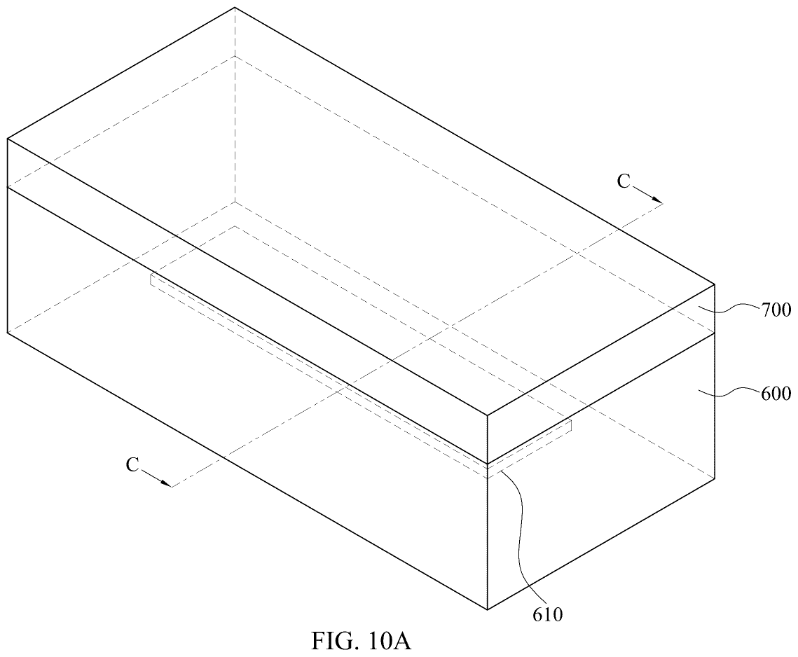

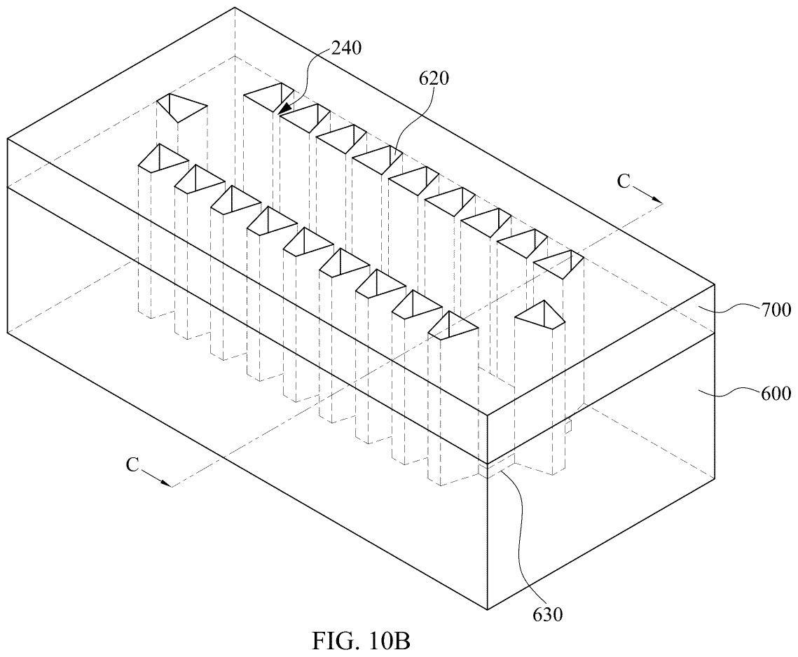

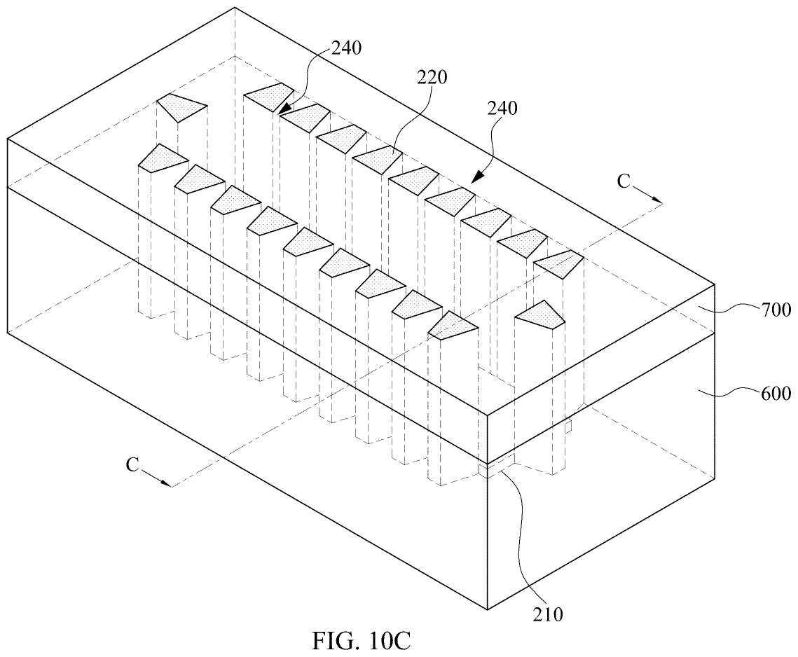

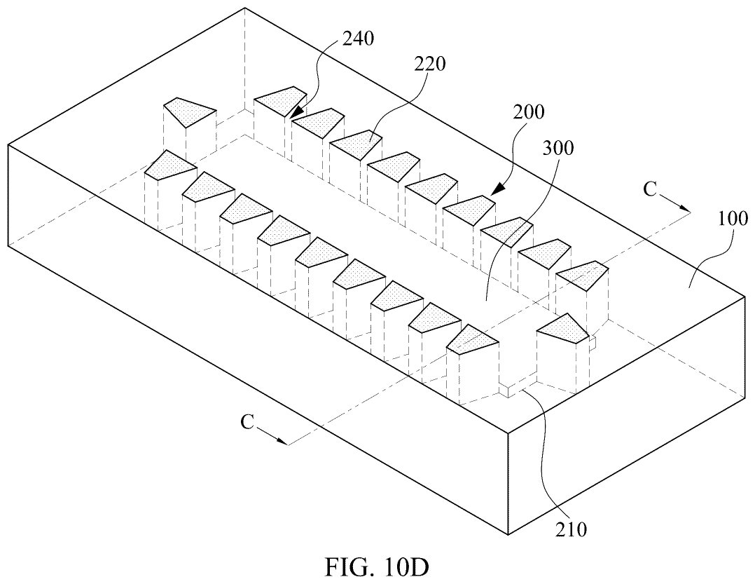

FIG. 9 is a flowchart representing a method 500 for forming a semiconductor device according to various aspects of the present disclosure. In some embodiments, the method 500 for forming the semiconductor device includes a number of operations (501, 502 and 503). The method 500 for forming the semiconductor device will be further described according to one or more embodiments. It should be noted that the operations of the method 500 may be rearranged or otherwise modified within the scope of the various aspects. It should further be noted that additional processes may be provided before, during, and after the method 500, and that some other processes may be only briefly described herein. FIGS. 10A to 10D are diagrammatic perspective views illustrating various stages in the method 500 for forming the connecting structure according to aspects of one or more embodiments of the present disclosure.

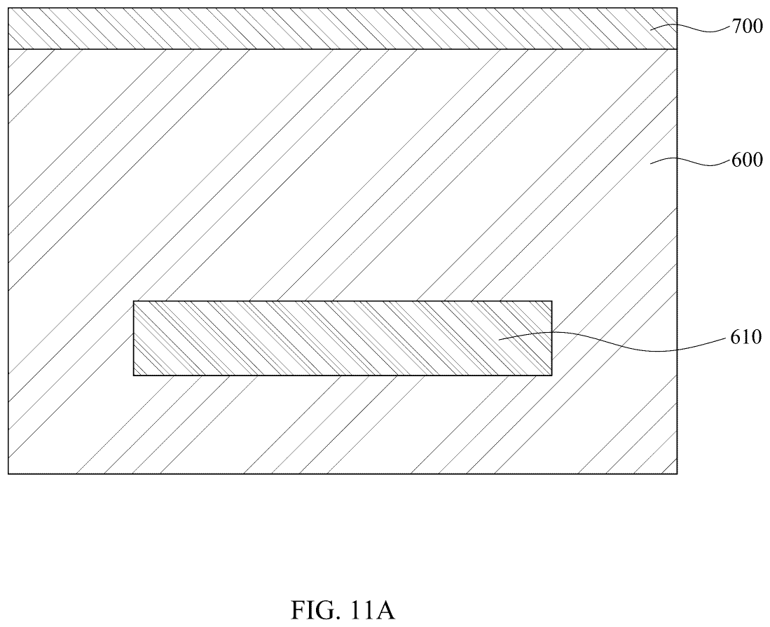

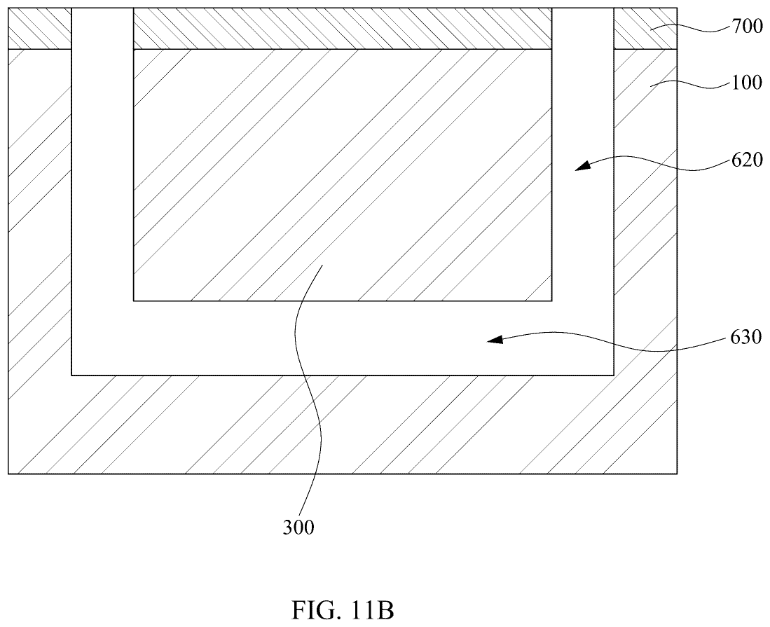

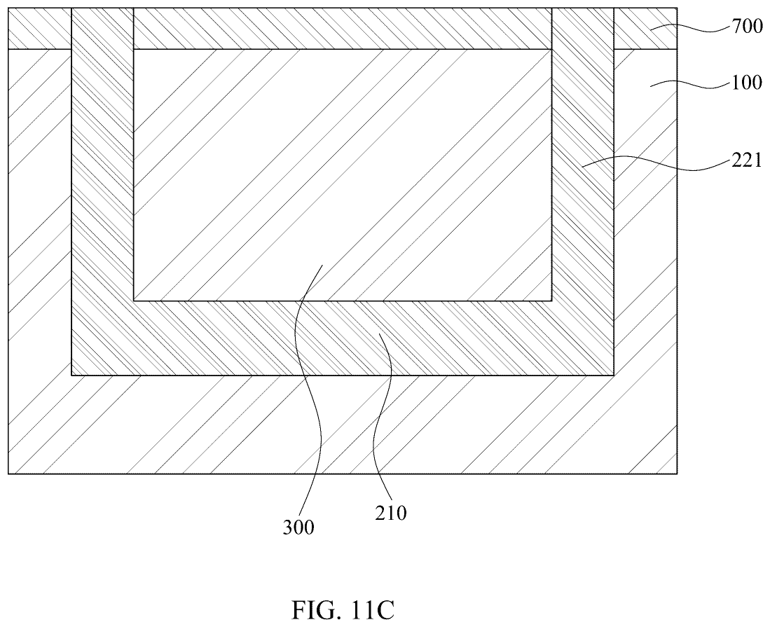

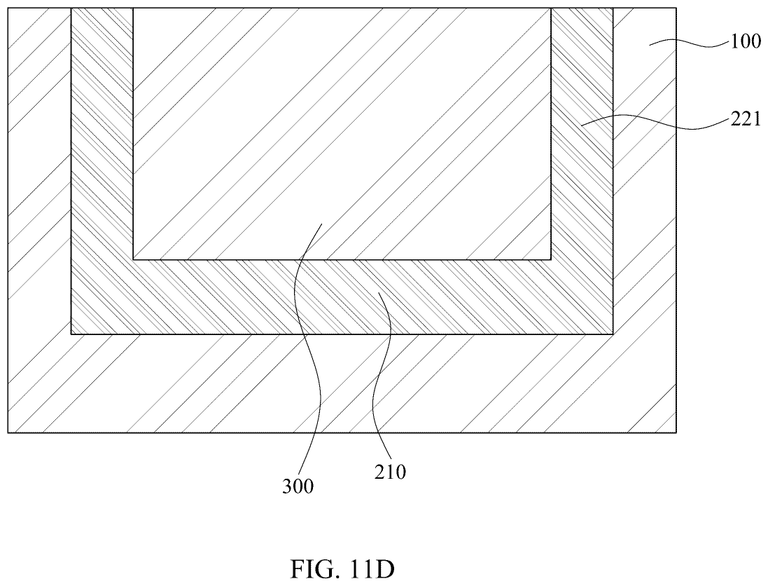

With reference to FIGS. 10A and 11A, the method 500 begins at operation 501 where an embedded doped region 610 is formed in a substrate 600 covered with a sacrificial layer 700. At operation 501, the substrate 600 is provided and received, which may be an N-type substrate or a P-type substrate; then, the sacrificial layer 700 is formed over the substrate 600 before forming the embedded doped region 610 through an implantation process. The sacrificial layer 700 may comprise nitride, silicon oxide or the like, which is used to protect the substrate 600 against damages (such as crystal damage) generated due to the following implantation processes, so as to ensure high device performance. In some embodiments, a thickness of the sacrificial layer 700 may be from about 40 Å to about 80 Å, but the disclosure is not limited thereto. In some comparative approaches, when the thickness of the sacrificial layer 700 is less than 40 Å, it would not be thick enough to protect the substrate 600. In other comparative approaches, when the thickness of the sacrificial layer 700 is greater than 80 Å, it would be too thick to block the following implantation.

According to some embodiments, the embedded doped region 610 is formed in the substrate 600 at a predetermined depth from a top of the substrate 600 through a vertical implantation or a tilt implantation. The dimension of the embedded doped region 610 can be customized based on device/circuit requirements. The embedded doped region 610 is formed by doping a predetermined area of the substrate 600 with dopants, so that the embedded doped region 610 has a high etching selectivity in respect to the substrate 600. For example, the dopants may be N-type or P-type dopant, including but not limited to B, Al, Ga, In, Ti, Nh, N, P, As, Sb, Bi or the like. The ion implantation energy, dosage, and temperature of the substrate 600 used during the implantation processes may be designed to control the penetration depth of the dopants in the substrate 600, so that the embedded doped region 610 can be formed at a predetermined depth in the substrate 600. The dopants in the embedded doped region 610 may diffuse into the substrate 600 to some extent, so a dopant concentration of dopants may be decreased from the embedded doped region 610 to the substrate 600 above and below the embedded doped region 610.

As shown in FIGS. 10B and 11B, the method 500 continues with operation 502 where a plurality of trenches 620 are formed at intervals 240 by etching the substrate 600 from the top of the substrate 600 downwardly to a depth aligned with a bottom of the embedded doped region 610; and laterally etching the embedded doped region 610 through the plurality of trenches 620 to form a lateral tunnel 630 as shown in FIG. 11B, which communicate the plurality of trenches 620. The plurality of trenches 620 are formed at intervals 240 by etching the substrate 600 from a top of the substrate 600 downwardly to a depth aligned with the bottom of the embedded doped region 610 to connect the embedded doped region 610. Since the plurality of trenches 620 are formed at intervals 240, collapse of the substrate can be prevented.

In some embodiments, the plurality of trenches 620 are formed using a dry etch process, a wet etch process, or a suitable process; and the lateral tunnel 630 is formed using a dry etch process, a wet etch process, or a suitable process. For example, the plurality of trenches 620 are formed using a dry etch process and the lateral tunnel 630 is formed using a wet etch process. Since the embedded doped region 610 comprises materials with a high etching selectivity in respect to the substrate 600, the formation of the lateral tunnel 630 can be formed in the embedded doped region 610. An example dry etch may use a fluorine-containing precursor (for example, CF₄, SF₆, NF₃, CH₂F₂, CHF₃, and/or C₂F₆), an oxygen-containing precursor, a chlorine-containing precursor (for example, Cl₂, CHCl₃, CCl₄, and/or BCl₃), a bromine-containing precursor (for example, HBr and/or CHBR₃), an iodine-containing precursor, other suitable precursor (which can be used to generate an etchant gas and/or etching plasma), or combinations thereof. An example of a wet etch process implements an etching solution that includes tetramethylammonium hydroxide (TMAH), NH₄OH, H₂O₂, H₂SO₄, HF, HCl, other suitable wet etching constituent, or combinations thereof.

The lateral etching may be even or uneven depending on the dimension of the embedded doped region 610, so a thickness of the lateral tunnel 630 may be consistent or inconsistent. For example, a thickness of the lateral tunnel 630 may be gradually decreased from an area near the trenches 620 to a central area away from the trenches 620. Therefore, the embedded doped region 610 may be remained in the semiconductor device of the substrate 600 near the insulating bottom 210 to be formed in the lateral tunnel 630 as shown in FIG. 3B.

At operation 503, with further reference to FIGS. 10C and 11C, the lateral tunnel 630 is filled with insulating materials to form an insulating bottom 210 and the plurality of trenches 620 are filled with insulating materials to form a plurality of insulating pillars 220, so the substrate 600 is divided into a first semiconductive region 100 and a second semiconductive region 300 by the isolation structure 200 including the insulating bottom 210 and the plurality of insulating pillars 220 while the first semiconductive region 100 and the second semiconductive region 300 may connect with each other through the intervals 240. The insulating materials include but not limited to oxide (such as SiO, doped SiO and so on), nitride (such as SiN), carbide (such as SiC), low k materials or a combination thereof. In some embodiments, the insulating materials may comprise silicon oxide, doped silicon oxide, silicon carbide, silicon nitride and so on. These are, of course, merely examples and are not intended to be limiting.

Before conducting following procedures, the sacrificial layer 700 can be removed as shown in FIGS. 10D and 11D to planarize and expose a top of the first semiconductive region 100, a top of the second semiconductive region 300 and upper surfaces of the plurality of insulating pillars 220.

The formation of the isolation structure 200 including the insulating bottom 210 and the insulating pillars 220, which are made of insulating materials, facilitate both process and electrical needs. The isolation structure 200 provides isolation on full direction, so the semiconductor device of the present disclosure without implanted area with junction isolation would not introduce extra parasitic capacitance. Circuit performance including improved parasitic capacitance and leakage can be achieved while maintaining the process convenience.

In some embodiments, a semiconductor device of the present invention comprises a first semiconductive region; a second semiconductive region formed in the first semiconductive region; and an isolation structure comprising: an insulating bottom formed between the first semiconductive region and the second semiconductive region; and a plurality of insulating pillars formed along a peripheral region of the insulating bottom at intervals and extending from the peripheral region of the insulating bottom toward a top of the first semiconductive region, so that the plurality of insulating pillars surround the second semiconductive region formed on the insulating bottom, wherein the first semiconductive region and the second semiconductive region connect with each other through the intervals.

In some embodiments, a semiconductor device of the present invention comprises a first semiconductive region; a second semiconductive region formed in the first semiconductive region; and an isolation structure comprising: an insulating bottom formed between the first semiconductive region and the second semiconductive region; and a plurality of insulating pillars surrounding the second semiconductive region formed along a peripheral region of the insulating bottom at intervals and extending from the peripheral region of the insulating bottom toward a top of the first semiconductive region, so that the plurality of insulating pillars surround the second semiconductive region formed on the insulating bottom, wherein a narrowest width of each of the interval between two of the plurality of insulating pillars is greater than 0 μm; and wherein a ratio of the narrowest widths of all of the intervals to a perimeter of the second semiconductive region ranges from about 5% to about 40%.

In some embodiments, a method for forming a semiconductor device of the present invention comprises forming an embedded doped region in a substrate; etching the substrate to form a plurality of trenches at intervals surrounding the embedded doped region and etching the embedded doped region to form a lateral tunnel; and filling the plurality of trenches with insulating materials to form a plurality of insulating pillars at the intervals and filling the lateral tunnel with insulating materials to form an insulating bottom, wherein a narrowest width of each of the interval between two of the plurality of insulating pillars is greater than 0 μm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor device comprising:
a first semiconductive region;
a second semiconductive region formed in the first semiconductive region; and
an isolation structure comprising:
an insulating bottom formed between the first semiconductive region and the second semiconductive region; and
a plurality of insulating pillars formed along a peripheral region of the insulating bottom at intervals and extending from the peripheral region of the insulating bottom toward a top of the first semiconductive region, so that the plurality of insulating pillars surround the second semiconductive region formed on the insulating bottom,
wherein the first semiconductive region and the second semiconductive region connect with each other through the intervals.

2. The semiconductor device of claim 1, wherein each of the plurality of insulating pillars has a trapezoid top cross section having a baseline and a topline, and wherein the baseline or the topline of each of the plurality of insulating pillars abuts the second semiconductive region.

3. The semiconductor device of claim 2, wherein a length between the baseline and the topline ranges from about 0.5 μm to about 4 μm.

4. The semiconductor device of claim 1, wherein the isolation structure further comprises at least one embedded doped region abutting the insulating bottom; and wherein the at least one embedded doped region comprises materials with a high etching selectivity in respect to the first semiconductive region and the second semiconductive region.

5. The semiconductor device of claim 1, wherein a thickness of the insulating bottom is decreased from a peripheral edge of the insulating bottom to a central portion of the insulating bottom.

6. The semiconductor device of claim 1, wherein the top of the first semiconductive region, a top of the second semiconductive region, and a top of the isolation structure are coplanar with each other.

7. The semiconductor device of claim 1, wherein each of the plurality of insulating pillars comprises different insulating materials.

8. A semiconductor device comprising:
a first semiconductive region;
a second semiconductive region formed in the first semiconductive region; and
an isolation structure comprising:
an insulating bottom formed between the first semiconductive region and the second semiconductive region; and
a plurality of insulating pillars surrounding the second semiconductive regionformed along a peripheral region of the insulating bottom at intervals and extending from the peripheral region of the insulating bottom toward a top of the first semiconductive region, so that the plurality of insulating pillars surround the second semiconductive region formed on the insulating bottom,
wherein a narrowest width of each of the interval between two of the plurality of insulating pillars is greater than 0 μm; and
wherein a ratio of the narrowest widths of all of the intervals to a perimeter of the second semiconductive region ranges from about 5% to about 40%.

9. The semiconductor device of claim 8, wherein the narrowest width of each of the interval between two of the plurality of insulating pillars ranges from about 0.1 μm to about 3 μm.

10. The semiconductor device of claim 8, wherein each of the plurality of insulating pillars has a trapezoid top cross section having a baseline and a topline and the baseline abuts the second semiconductive region.

11. The semiconductor device of claim 10, wherein a ratio of the narrowest widths of all of the intervals to total widths of the baseline of all of the plurality of insulating pillars ranges from about 10% to about 50%.

12. The semiconductor device of claim 10, wherein a length between the baseline and the topline ranges from about 0.5 μm to about 4 μm.

13. The semiconductor device of claim 8, wherein the plurality of insulating pillars surrounding the second semiconductive region have a same shape.

14. The semiconductor device of claim 8, wherein the second semiconductive region is a tetrahedron; and the plurality of insulating pillars comprising four L-shape insulating pillars formed at four corners of the second semiconductive region.

15. The semiconductor device of claim 8, wherein each of the plurality of insulating pillars has a triangular top cross section, a rectangular top cross section or a polygonal top cross section.

16. A method for manufacturing a semiconductor device, comprising:
forming an embedded doped region in a substrate;
etching the substrate to form a plurality of trenches at intervals surrounding the embedded doped region and etching the embedded doped region to form a lateral tunnel; and
filling the plurality of trenches with insulating materials to form a plurality of insulating pillars at the intervals and filling the lateral tunnel with insulating materials to form an insulating bottom,
wherein a narrowest width of each of the interval between two of the plurality of insulating pillars is greater than 0 μm.

17. The method of claim 16, wherein the embedded doped region is partially retained after the formation of the lateral tunnel.

18. The method of claim 16, wherein after the formation of the plurality of insulating pillars and the insulating bottom, the substrate and the plurality of insulating pillars are planarized.

19. The method of claim 16, wherein the plurality of trenches are formed by dry etching the substrate and the lateral tunnel is formed by wet etching the embedded doped region.

20. The method of claim 16, wherein the embedded doped region has a high etching selectivity in respect to the substrate.
